(19) United States
(12) Patent Application Publication
(10) Pub. No.: US 2025/0393358 A1
(43) Pub. Date: Dec. 25, 2025

(54) LIGHT-EMITTING DIODE DISPLAY DEVICE

(71) Applicant: Sulin Yang, St. Augustine, FL (US)

(72) Inventor: Sulin Yang, St. Augustine, FL (US)

(21) Appl. No.: 18/978,840

(22) Filed: Dec. 12, 2024

(30) Foreign Application Priority Data
Jun. 19, 2024 (TW) 113122657

(51) Int. Cl. H10H 29/49; H01L 25/075; H01L 25/16

(52) U.S. Cl. CPC H10H 29/49; H01L 25/167; H01L 25/0753

(57) ABSTRACT

The disclosure describes a light-emitting diode (LED) display device with a control circuit layer, multiple electrodes, multiple LEDs, and a common electrode layer. The control circuit layer is coupled with multiple scan lines and data lines, with the scan lines and data lines intersecting substantially perpendicularly. The electrodes are positioned on the control circuit layer and coupled to the control circuit layer, with all electrodes electrically isolated. The LEDs are respectively placed on the electrodes and are coupled to them, arranged in an array. The common electrode layer comprises multiple equivalent one-dimensional (1D) electrode strips. The different ends of the equivalent 1D electrode strips connect to a supply voltage. The equivalent 1D electrode strips are respectively placed on multiple columns of the LED array and are coupled to multiple columns of the LED array, intersecting the scan lines substantially perpendicularly.

### BACKGROUND OF THE INVENTION

This application claims priority for the TW patent application No. 113122657 filed on 19 Jun. 2024, the content of which is incorporated by reference in its entirely.

### FIELD OF THE INVENTION

The invention relates to a display device, specifically a light-emitting diode (LED) display device.

### DESCRIPTION OF THE RELATED ART

Backlit liquid crystal (LC), semiconductor light-emitting diode (LED), and organic light-emitting diode (OLED) devices have been widely used in modern flat-panel displays, such as computer monitors, smartphone screens, and automotive displays. With the growing demand for more advanced visual devices in fields like virtual reality (VR), augmented reality (AR), and mixed reality (MR), there is increasing consideration of using micro light-emitting diode (micro-LED) and micro-OLED displays to meet the requirements for high resolution and high-density display manufacturing.

Pixels are the fundamental elements that make up images on a screen. In hardware, each pixel can be individually controlled to display text, graphics, images, or dynamic video. To manage power constraints and the required photon output, scanning technology addresses multiple rows of pixels simultaneously, sequentially lighting different image sections. The scanning rate and the number of frames per second (typically between 30 and 240 Hz) determine the overall frame rate. At a given frame rate, the number of pixel rows scanned at once affects the relative brightness of the display. Additionally, the duration of pixel activation under set electrical conditions ensures adequate brightness, which is a standard specification in display technology.

Different types of flat-panel displays are composed of various structural components. In general, flat-panel displays consist of three main types of components:
1. Pixelated photon-emitting elements: These elements are located on the front plane of the display and utilize technologies such as semiconductor light-emitting diodes (LED) and organic light-emitting diodes (OLED). They emit light to form images.
2. Pixelated Complementary Metal-Oxide Semiconductor (CMOS) electronic control and regulation components: These components are located in the backplane of the pixel array and include elements like the pixel drive circuit (PDC) combined with a current-regulating source. They control the operation of the pixelated photon-emitting elements.
3. Integrated global circuits: The display's backplane circuitry is responsible for signal data processing, such as pulse-width modulation (PWM) circuits and row selection within a frame. It primarily uses a line-scanning scheme to coordinate pixel activation.

Both ends of the pixelated elements can be activated throughout the frame using a scanning method on the photonic section of the front plane. The electrodes can be configured as common anode (CA) or common cathode (CC) pixelated light-emitting components, enabling the display of images on a flat-panel display.

Conductive metals lack optical transparency and are typically used as electrodes in pixel array displays. The areas of these metal electrodes that do not cover the pixel illumination areas play a crucial role in determining the optical aperture ratio of the pixels, directly affecting the light emission efficiency and brightness produced by the pixels. Ideally, the layout of electrodes should minimize interference with pixel illumination. However, this creates a significant resistance between the pixel nodes and the voltage source terminals, increasing the impact of current resistance (IR) voltage drop. This behavior can negatively affect the uniformity of pixel performance across the entire array.

As displays move toward higher resolution and denser pixel layouts, requiring smaller light-emitting element sizes, the trade-off between the final aperture ratio and conductance of the common electrode becomes more complex. Under these conditions, optimizing electrode materials and structures becomes crucial.

Solving the challenge of IR voltage drop and its impact on uneven pixel luminescence and thermal energy waste depends in part on the program control of the line pixel activation algorithm and operational processing according to specific conditions. A comprehensive solution to the IR-drop problem of LED and OLED displays has yet to be generally established.

Therefore, this invention addresses the issues above by proposing a light-emitting diode display device to solve the problems present in conventional technologies.

### SUMMARY OF THE INVENTION

This invention provides a light-emitting diode display device that reduces the impact of the current resistance (IR) drop in the common electrode layer and increases the pixel aperture ratio. As a result, the uniformity of pixel light emission is improved, achieving excellent pixel emission performance and efficiency. Additionally, by consuming less power to thermal energy, the display device can exhibit stable performance and have a longer lifespan.

In one embodiment of the present invention, a light-emitting diode (LED) display device includes a control circuit layer, multiple electrodes, multiple LEDs, and a common electrode layer. The control circuit layer is coupled to multiple scanning lines and data lines, which substantially intersect perpendicularly. The electrodes are placed on the control circuit layer and coupled to it, with the electrodes being isolated from each other. The LEDs are arranged in an array, each with two terminal electrodes. One terminal electrode of each LED is coupled to a corresponding electrode on the control circuit layer, and the other terminal electrode of the LED is connected to the common electrode layer. The common electrode layer consists of multiple equivalent one-dimensional electrode strips. At least one end of each equivalent one-dimensional electrode strip is coupled to a supply voltage, and the strips are respectively positioned along multiple columns of the LED array, coupled to the multiple columns of the LED array, and substantially intersected perpendicularly with the scanning lines.

In one embodiment of the present invention, the common electrode layer includes multiple groups of one-dimensional electrode segments coupled to the equivalent one-dimensional electrode strips, with the groups arranged in parallel. Each group of one-dimensional electrode segments contains multiple one-dimensional electrode segments coupled to the equivalent one-dimensional electrode strips and arranged alternately with the equivalent one-dimensional electrode strips, positioned substantially perpendicularly to them. For visible applications, the width of each equivalent one-dimensional electrode strip is greater than that of each one-dimensional electrode segment.

In one embodiment of the present invention, the LED display device includes a first-driver integrated circuit and a second-driver integrated circuit. The first driver-integrated circuit is coupled to the scanning lines, and the second to the data lines.

In one embodiment of the present invention, the control circuit layer includes multiple control circuits arranged in an array. The multiple columns of control circuits are coupled to the data lines, and the multiple rows of control circuits are coupled to the scanning lines. The electrodes are placed on the control circuits and are respectively coupled to them.

In one embodiment of the present invention, the equivalent one-dimensional electrode strips are made of conductive material.

In one embodiment of the present invention, the light-emitting diodes are semiconductor or organic light-emitting diodes.

In one embodiment of the present invention, each light-emitting diode is a monochrome or multi-color diode.

In one embodiment of the present invention, individual electrodes serve as cathodes, while the common electrode layer serves as the anode.

In one embodiment of the present invention, individual electrodes serve as anodes, while the common electrode layer is the cathode.

In one embodiment of the present invention, one end or both ends of each equivalent one-dimensional electrode strip are coupled to a supply voltage.

Based on the above, the LED display device forms equivalent one-dimensional electrode strips that intersect the scanning lines perpendicularly, reducing the impact of current resistance (IR) voltage drop in the common electrode layer. This embodiment simultaneously increases the pixel aperture ratio, achieving outstanding pixel luminous efficiency and uniformity while dissipating less thermal energy and enhancing the stability and lifespan of the display device.

Below, the embodiments are described in detail in cooperation with the drawings to make the invention's technical contents, characteristics, and accomplishments easily understood.

### BRIEF DESCRIPTION OF THE DRAWINGS

FIG. 1 is a schematic diagram of a light-emitting diode according to an embodiment of the present invention;

FIG. 2 is a schematic diagram of a light-emitting diode disposed on a control circuit layer according to an embodiment of the present invention;

FIG. 3 is a schematic diagram of a light-emitting diode disposed on a control circuit layer according to another embodiment of the present invention;

FIG. 4 is a schematic diagram of a light-emitting diode display device with a common electrode layer;

FIG. 5 is an equivalent circuit diagram corresponding to FIG. 4;

FIG. 6 is another equivalent circuit diagram corresponding to FIG. 4;

FIG. 7 is a schematic diagram of a light-emitting diode display device having equivalent one-dimensional electrode strips parallel to the scanning lines;

FIG. 8 is an equivalent circuit diagram corresponding to FIG. 7;

FIG. 9 is another circuit diagram equivalent to FIG. 7;

FIG. 10 is a schematic diagram of a light-emitting diode display device according to an embodiment of the present invention;

FIG. 11 is an equivalent circuit diagram corresponding to FIG. 10;

FIG. 12 is another circuit diagram equivalent to FIG. 10;

FIG. 13 is another circuit diagram equivalent to FIG. 10;

FIG. 14 is another circuit diagram equivalent to FIG. 10; and

FIG. 15 is a schematic diagram of a light-emitting diode display device according to another embodiment of the present invention.

### DETAILED DESCRIPTION OF THE INVENTION

The embodiments of the present invention will be further explained below concerning relevant figures. The same reference numbers are used in the drawings and description wherever possible to refer to the same or similar components. In the drawings, shapes and thicknesses may be exaggerated for simplicity and ease of notation. It should be understood that elements not explicitly shown in the drawings or described in the specification are in forms known to those of ordinary skill in the art. Those skilled in the art can make various changes and modifications based on the contents of the present invention.

When a component is referred to as “on,” it can refer to that component being directly on another element, or it can also mean that other components are present between the two. Conversely, when a component is referred to as “directly on” another component, there cannot be any other components between the two. As this document uses, “and/or” encompasses any combination of one or more related items.

The description of “one embodiment” or “an embodiment” in the following text refers to a specific component, structure, or feature associated with at least one embodiment. Therefore, the text's multiple references to “one embodiment” or “an embodiment” do not refer to the same embodiment. Furthermore, the specific components, structures, and features in one or more embodiments may be combined appropriately.

The disclosure describes explicitly the following examples, which are only for illustrative purposes. For those familiar with this technology, various modifications and refinements can be made without departing from the spirit and scope of this disclosure. Therefore, the protection scope of this disclosure should be defined by the following claims. Throughout the specification and the claims, unless specified otherwise, the terms “a” and “the” include instances of “one or at least one” of the component or ingredient. Furthermore, as used in this disclosure, unless it is evident from the specific context that plural forms are excluded, singular articles also encompass plural components or ingredients. Additionally, when applying the descriptions herein and in the following claims, unless specified otherwise, the term “therein” may include “therein” and “thereon.” In terms of terminology used throughout the specification and claims, unless expressly noted, each term typically carries its ordinary meaning in the field, within the context of this disclosure, and in the particular context. We want to discuss specific terms used to describe this disclosure further below or elsewhere in this specification to provide practitioners with additional guidance regarding the description of this disclosure. Any examples provided throughout this specification, including the use of any terms discussed here, are illustrative and do not limit the scope and meaning of this disclosure or any illustrative terms. Similarly, this disclosure is not limited to the various embodiments presented in this specification.

It can be understood that the terms used herein, such as ‘comprising,’ ‘including,’ ‘having,’ ‘containing,’ ‘involving,’ etc., are open-ended, meaning they include but are not limited to the listed items. Furthermore, any embodiment of the present invention or the scope of the patent application can achieve some of the purposes, advantages, or features disclosed in this invention. Additionally, the abstract and title are intended solely to assist in searching patent documents and are not meant to limit the scope of the invention claimed.

Furthermore, the term ‘electrical coupling’ or ‘electrical connection’ herein includes any direct or indirect electrical connection means. For example, suppose the text describes a first device electrically coupled to a second device. In that case, the first device can be directly connected to the second device or indirectly connected to the second device through other devices or connection means. Additionally, when describing the transmission or provision of electrical signals, those skilled in the art should understand that the transmission of electrical signals may be accompanied by attenuation or other non-ideal variations. However, if the source and receiving end of the electrical signal transmission or provision are not explicitly stated, they should be regarded as effectively the same signal. For instance, if an electrical signal S is transmitted (or provided) from endpoint A of an electronic circuit to endpoint B of the electronic circuit, there may be a voltage drop across the source and drain of a transistor switch and/or possible stray capacitance; however, if the design does not intentionally use the attenuation or other non-ideal variations generated during transmission (or provision) to achieve specific technical effects, the electrical signal S at endpoints A and B of the electronic circuit should be considered effectively the same signal.

Unless otherwise specified, specific conditional phrases or terms such as ‘can,’ ‘could,’ ‘might,’ or ‘may’ typically attempt to express features that are present in this embodiment but can also be interpreted as characteristics, components, or steps that may not be necessary. In other embodiments, these features, components, or steps may be unnecessary.

The terms ‘substantially,’ ‘around,’ ‘about,’ or ‘approximately’ used herein generally mean within 20% of a given value or range, preferably within 10%. Furthermore, the quantities provided here may be approximations, which means that in the absence of specific statements, they can be indicated by the terms ‘around,’ ‘about,’ or ‘approximately.’ When a quantity, concentration, or other numerical value or parameter has a specified range, preferred range, or ideal values listed, it should be understood as specifically disclosing all ranges constituted by any pairs of lower and upper limits or ideal values, regardless of whether those ranges are separately disclosed. For example, suppose a disclosed range states that a length is from X centimeters to Y centimeters. In that case, it should be considered as revealing a length of H centimeters, where H can be any actual number between X and Y.

The term ‘effective one-dimensional electrode strip’ herein refers to a one-dimensional electrode strip with varying widths along the main line direction. It may possess structural variations in the transverse local shape, such as a serrated pattern. The degree of variation in these effective widths is less than 10% of the length of the one-dimensional electrode strip.

The following describes the invention's light-emitting diode display device, which forms equivalent one-dimensional electrode strips that intersect perpendicularly with the scan lines. This configuration reduces the impact of current resistance (IR) voltage drop in the common electrode layer and increases the pixel aperture ratio. As a result, it achieves excellent pixel luminous efficiency and uniformity in emission while operating under conditions that generate lower thermal power, leading to stable performance of the light-emitting device and a longer component lifespan.

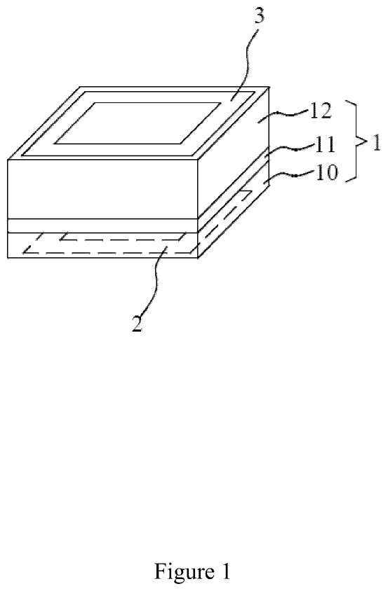

FIG. 1 is a schematic diagram of a light-emitting diode in an embodiment of the present invention. Referring to FIG. 1, a typical light-emitting diode 1 includes a first semiconductor layer 10, a quantum well layer 11, and a second semiconductor layer 12, stacked in that order. Electrodes 2 and 3 are respectively placed on the first semiconductor layer 10 and the second semiconductor layer 12. The first semiconductor layer 10 and the second semiconductor layer 12 have a first conductivity type and its opposite second conductivity type, respectively. When the first conductivity type is N-type, the second conductivity type is P-type. Conversely, when the first conductivity type is P-type, the second conductivity type is N-type.

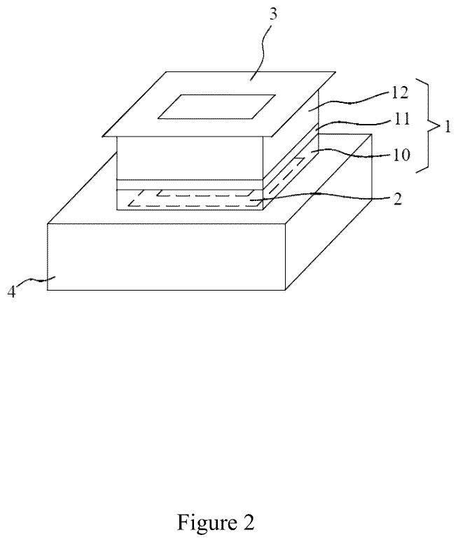

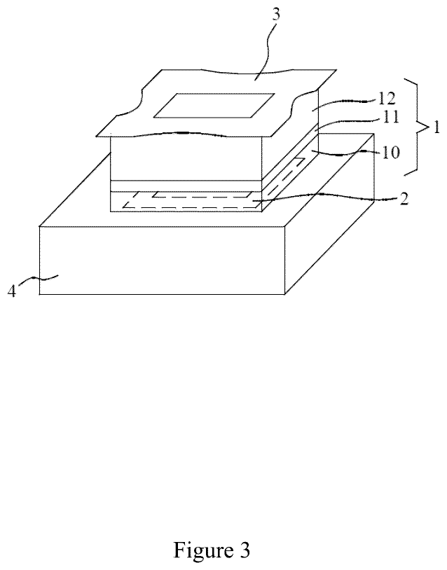

FIG. 2 is a schematic diagram showing a light-emitting diode of an embodiment of the present invention positioned on a control circuit layer. Referring to FIG. 2, the first semiconductor layer 10 is placed on a control circuit layer 4 through electrode 2 to facilitate pixel operation control. Electrode 3 partially covers the second semiconductor layer 12 within the pixel. FIG. 3 is a schematic diagram of a light-emitting diode in another embodiment of the present invention, situated on a control circuit layer. FIG. 3 depicts an electrode 3 similar to that in FIG. 2, characterized by cutouts on its four sides, which are optional and unnecessary in some cases. This design allows electrode 2 to pass through the isolated pixel sidewalls, although this is not explicitly shown here. This configuration is particularly significant for stacking tricolor light-emitting diodes, aiding their integration with the control circuit layer 4, even though this is not illustrated in the figure. Such integration enhances the overall functionality and performance of the light-emitting diode array.

Various methods and techniques can be employed to create light-emitting diode (LED) pixel arrays and display panels. Control circuits connected to the scan, data, and clock lines can utilize complementary metal-oxide-semiconductor (CMOS) pixel driving circuits (PDC). This enables displaying images and videos in different scanning modes, including single-pixel, multi-pixel, and pixel line scan modes. In the well-known line scanning mode, the LED pixels are configured either as the common anode (CA) or a common cathode (CC). This allows the electrodes of each pixel to connect to their respective PDCs and compatible current regulation circuits within the (m×n) pixel array. This scheme provides high-quality image and video displays at standard resolutions, such as 640×360 for one-ninth HD (nHD), 1280×640 for HD, and 1920×1080 for full HD (FHD).

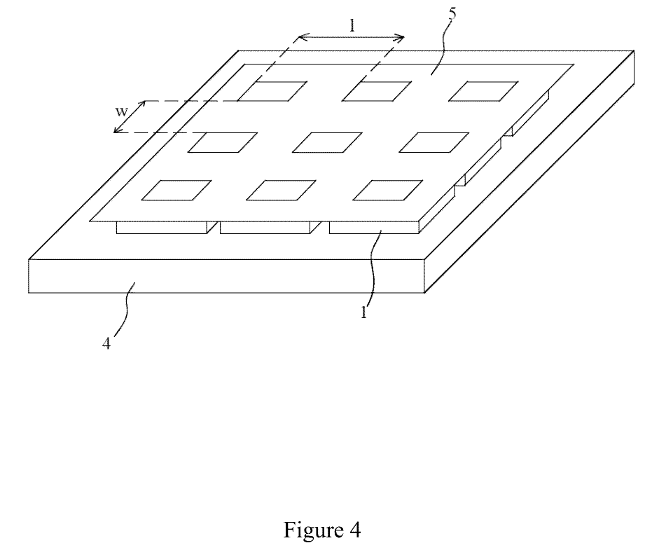

FIG. 4 is a schematic diagram of a light-emitting diode display device with a common electrode layer. Referring to FIGS. 2 and 4, electrode 3 in FIG. 2 extends outward to form the common electrode layer 5, shown in FIG. 4. The common electrode layer 5 is arranged in a two-dimensional grid pattern, forming multiple electrodes 2 on the control circuit layer 4, which are connected to the (m×n) electrodes 2 of the light-emitting diodes 1, thus creating the light-emitting diode display device illustrated in FIG. 4. Both m and n are positive integers greater than 1. In this example, both m and n are equal to 3.”

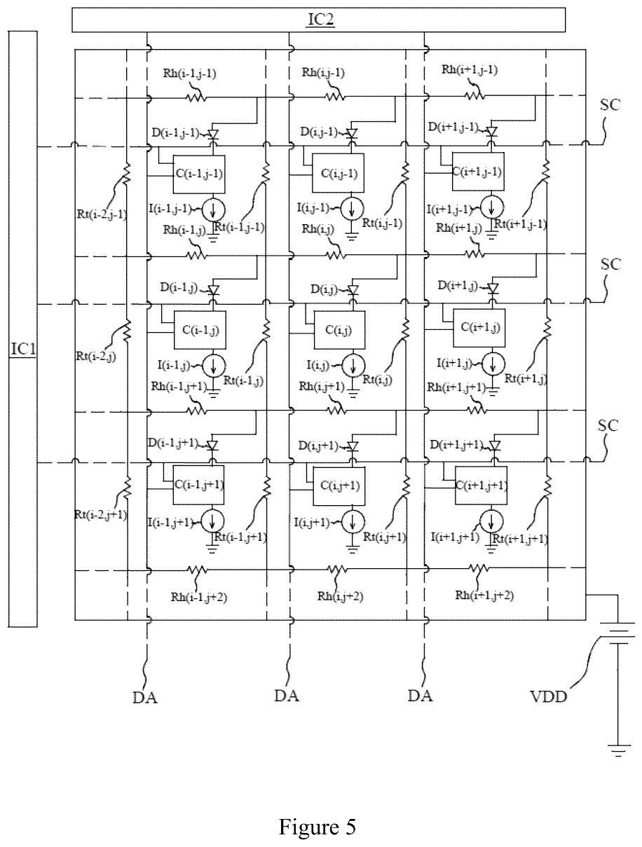

FIG. 5 corresponds to FIG. 4 but features a non-limited size (m×n) light-emitting diode (LED) array and additionally includes an equivalent circuit diagram supplying a voltage VDD. Please refer to FIGS. 2, 4, and 5. The common electrode layer 5 contains multiple horizontal and transverse parasitic resistors. The corresponding horizontal and transverse parasitic resistors in each LED unit arise from the limited conductivity of the wiring, the finite thickness of the wiring, and its effective width. The horizontal and transverse parasitic resistors are coupled and connected to a terminal that supplies the voltage VDD. The horizontal parasitic resistor in the i-th column and the j-th row is represented as Rh(i,j), the transverse parasitic resistor in the i-th column and the j-th row is represented as Rt(i,j), and the LED in the i-th column and the j-th row is represented as D(i,j), where both i and j are positive integers greater than 0. The control circuit layer 4 includes multiple control circuits and current sources, the first driving integrated circuit IC1 and the second driving integrated circuit IC2. The current source in the i-th column and the j-th row is represented as I(i,j), and the control circuit in the i-th column and the j-th row is represented as C(i,j). Each control circuit is coupled to a scan line SC and a data line DA; the scan line SC is coupled to the first driving integrated circuit IC1 and is used to transmit pulse width modulation voltage, while the data line DA is coupled to the second driving integrated circuit IC2. Each control circuit is coupled to a ground through its corresponding current source. In this embodiment, the common electrode layer 5 serves as the anode of LED 1, electrode 2 serves as the cathode of LED 1, the first conductivity type of the first semiconductor layer 10 is N-type, and the second conductivity type of the second semiconductor layer 12 is P-type.

The compliance-regulated current source I(i,j) for each pixel may not be necessary for the light-emitting displays. However, such compliance, regulation, or reference current sources can effectively control high-quality flat-panel displays that require uniform pixel brightness behavior. It ensures consistent current flow through all pixels, producing uniform brightness during the same active period. This is especially true regardless of the voltage drop across the light-emitting diode during operation. Since the light-emitting elements in the same device generally have similar external quantum efficiency (EQE), a relatively good uniformity of light emission can be achieved. Otherwise, controlling or setting the voltage across the light-emitting device might take a lot of work.

In a simplified analysis, the parallel row or column traces intersecting at the pixel edges can be collectively referred to as a single row or column trace, with its effective width denoted as w. Therefore, the parasitic resistance value of the horizontal standard electrode layer 5 for each pixel can be calculated using the formula ρ·l/(w·t), where ρ represents the resistivity of the common electrode layer 5, l is approximately the pixel pitch, w is the effective width of the cross-section of the strip portion surrounding the pixel, and t is the thickness of the common electrode layer 5. Due to the symmetrical configuration of the mesh electrodes in both the horizontal and transverse directions, the value of the horizontal parasitic resistance can be considered approximately equal to that of the transverse parasitic resistance.

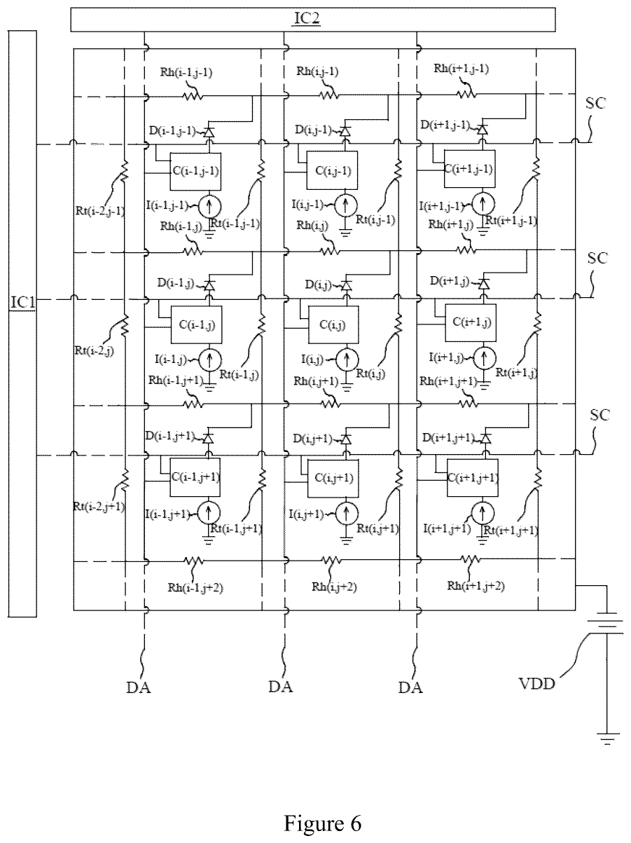

FIG. 6 is another equivalent circuit diagram corresponding to FIG. 4, showing an array of (m×n) light-emitting elements and the supply voltage VDD. FIG. 6 is similar to FIG. 5. Please refer to FIGS. 2, 4, and 6: the common electrode layer 5 serves as the cathode of the light-emitting diode 1, and electrode 2 serves as the anode of the light-emitting diode 1. The first conductivity type of the first semiconductor layer 10 is P-type, and the second conductivity type of the second semiconductor layer 12 is N-type. Therefore, the current direction of the current source in FIG. 6 is opposite to that in FIG. 5. Despite the polarity and current direction differences between the common-anode and common-cathode cases, their behavior, trends, and final effects remain consistent.

To improve the efficiency of standard LED displays, the supply voltage VDD is typically adjusted within the range of 3-5V, customized explicitly for red, green, and blue light-emitting diodes. This voltage can be fine-tuned to minimize power consumption, ensuring that the light-emitting diodes in the pixels operate within the saturation current region controlled by a compatible current source.

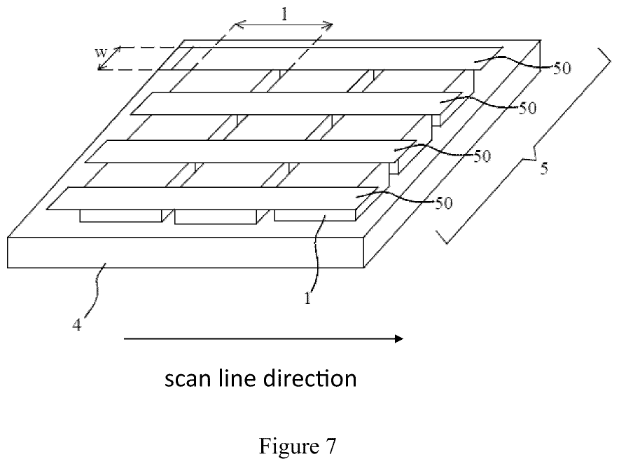

FIG. 7 illustrates a schematic of a light-emitting diode display device with equivalent one-dimensional electrode strips parallel to the scan lines. The direction of the scan line is marked for reference. Please refer to FIGS. 4 and 7; FIGS. 4 and 7 differ in the shape of the common electrode layer 5. The two-dimensional grid shape of the common electrode layer 5 in FIG. 4 is replaced by multiple equivalent one-dimensional electrode strips 50, forming the common electrode layer 5 in FIG. 7, where the equivalent one-dimensional electrode strips 50 are parallel to the scan lines. Compared to FIG. 4, the area of the common electrode layer 5 in FIG. 7 is reduced by about half, which decreases the coverage of the illuminating region of the light-emitting diodes, allowing for a larger optical aperture. Therefore, when operating under the same bias conditions and without other influencing factors, pixels with equivalent one-dimensional electrode strips can achieve higher light-emitting efficiency than pixels with a two-dimensional grid-shaped common electrode layer.

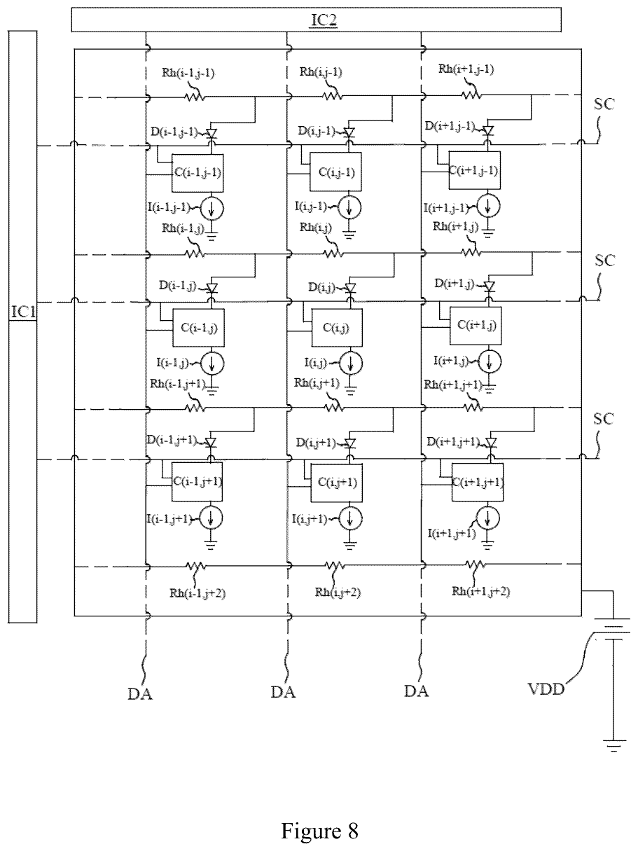

FIG. 8 corresponds to FIG. 7 but features a light-emitting diode array of unspecified size (m×n) and additionally includes the equivalent circuit diagram for the supply voltage VDD. FIG. 8 omits the transverse parasitic resistance compared with FIG. 5. The other features remain the same as in FIG. 5 and will not be repeated here. As shown in FIGS. 7 and 8, the horizontal parasitic resistance value of the common electrode layer 5 for each pixel is calculated using the formula ρ·l/(w·t), where ρ represents the resistivity of the common electrode layer 5, l is approximately the pixel pitch, w is the effective width of the cross-sectional strip surrounding the pixel, and t denotes the thickness of the common electrode layer 5.

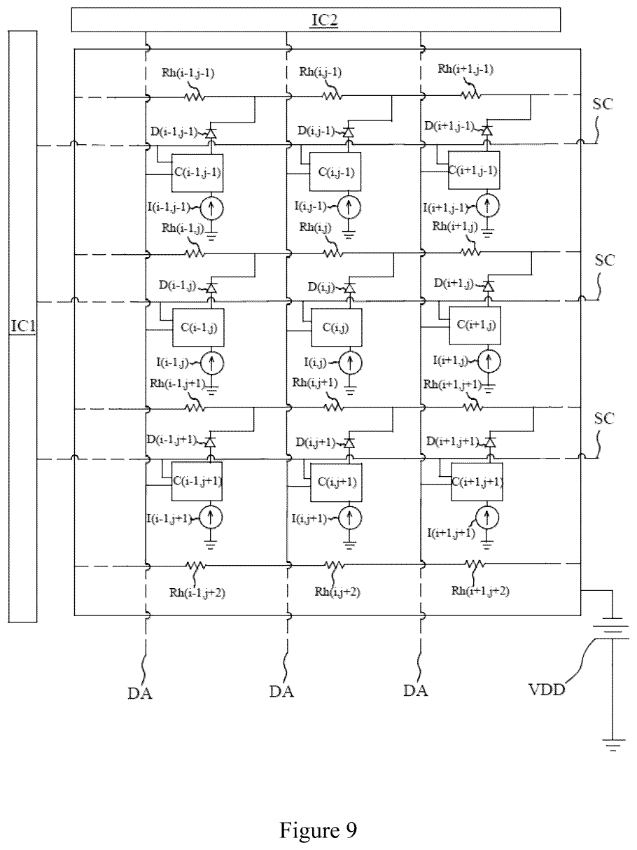

FIG. 9 is a counterpart to FIG. 7, presenting another equivalent circuit diagram of the (m×n) light-emitting element array with supply voltage VDD. Unlike FIG. 6, FIG. 9 omits the transverse parasitic resistance; however, all other features are identical to those in FIG. 6 and will not be repeated here.

As mentioned earlier, the current source I(i,j) values are uniformly set to a constant value to ensure consistent lighting conditions for the pixel LEDs, achieving a high degree of uniformity in image display. Systemically, the entire (m×n) display device can simultaneously activate multiple designated rows of LEDs within the scanning interval to achieve the desired image brightness.

The resistance values of all horizontal parasitic resistors are typically the same, ensured through standard design rules and manufacturing processes that maintain a constant resistance value for the horizontal parasitic resistors. These horizontal parasitic resistors create what is commonly called “IR voltage drop.” All selected active pixels are assumed to receive the same current to evaluate the IR voltage drop effect generated by the common electrode layer coupled to the supply voltage VDD. Considering symmetry and that both ends of a one-dimensional electrode line are connected to the supply voltage VDD, half of the pixels receive current from one side.

In an LED array with m columns and n rows, selecting the LED D(i,j) for scanning refers to choosing the diode in the i-th column and j-th row for activation. Here, it is assumed that i=m/2, positioning the selection in the central row. A constant compliance reference current Iref flows through the horizontal parasitic resistor Rh(m/2,j) to the anode or cathode of the light-emitting diode D(m/2,j), resulting in a voltage drop across both ends of the horizontal parasitic resistor equal to Rh×Iref, where Rh represents the resistance value of the horizontal parasitic resistor, and Iref represents the current flowing through each light-emitting diode D(i,j), which is the current of the current source I(i,j).

The current through the horizontal parasitic resistor Rh(m/2−1,j) is composed of the current Iref through the anode or cathode of the light-emitting diode D(m/2−1,j) and the current Iref through the horizontal parasitic resistor Rh(m/2,j). Similarly, the current through the horizontal parasitic resistor Rh(1,j) is composed of the current Iref through the anode or cathode of the light-emitting diode D(1,j) and the current flowing through the horizontal parasitic resistor Rh(2,j). Since the current through the horizontal parasitic resistor Rh(2,j) is equal to (m/2−1)×Iref, the voltage drop across both ends of the horizontal parasitic resistor Rh(1,j) is equal to (m/2)×Iref×Rh.

Therefore, in the case of scanning lines being parallel to an equivalent one-dimensional electrode strip, the maximum voltage difference between the supply voltage VDD and the anode or cathode of the light-emitting diode located in the middle of the pixel array, represented as V_{HR,max}, is approximately as shown in formula (1).

$$\begin{matrix}{V}_{HR , max} = {\sum }_{i = 1}^{i = \frac{m}{2}} [ ( \frac{m}{2} - i + 1 ) \times Iref \times Rh ] \\ = ( m ( m + 2 ) ) / 8 \times Iref \times Rh \\ = {m}^{2} / 8 \times Iref \times Rh , if m ≫ 1\end{matrix} \qquad ( 1 )$$

When m, Iref, and Rh are predetermined, V_{HR,max} remain constant. Specifically, V_{HR,max} are approximately equal to

$$\frac{{m}^{2}}{8} \times Iref \times Rh .$$

The thermal power generated by the IR voltage drop effect is explicitly related to the horizontal parasitic resistance in each row of the selected active lines. This phenomenon can be expressed through the relationship between electrical power W, voltage V, and current I, where W=I×V. The electrical power converted into heat for each equivalent one-dimensional electrode strip is represented as W_{HR1} and can be calculated using Formula (2).

$$\begin{matrix}{W}_{HR 1} = 2 \times {\sum }_{i = 1}^{i = \frac{m}{2}} \{ {[ ( \frac{m}{2} - i + 1 ) \times Iref ]}^{2} \times Rh \} \\ = 2 \times [ m / 2 \times ( m / 2 + 1 ) \times ( m + 1 ) ) / 6 ] \times {Iref}^{2} \times Rh \\ \approx \frac{{m}^{3}}{12} \times {Iref}^{2} \times Rh , if m ≫ 1\end{matrix} \qquad ( 2 )$$

The multiplication factor of 2 indicates the two symmetrical halves of the pixel row. For each scan with k selected row lines in an (m×n) pixel array, the total power W_{HR} dissipated in heat by the equivalent one-dimensional electrode strips is k×W_{HR1}. This can be expressed as Formula (3).

$${W}_{HR} = \frac{m / 2 \times ( m / 2 + 1 ) \times ( m + 1 )}{3} \times {Iref}^{2} \times {R}_{h} \times k \qquad ( 3 )$$

In the example of a micro-LED display with a 1280×720 high-definition pixel array and a pixel pitch of 5 μm, each pixel's estimated horizontal parasitic resistance is approximately 0.5 ohms. This estimate uses copper as the material for the equivalent one-dimensional electrode strip, with a resistivity of 1.77×10⁻⁸ Ω·m. Assuming the effective width of the equivalent one-dimensional electrode strip is 1 μm and the thickness is 0.18 μm, these dimensions align with the geometric sizes of the pixel structure and semiconductor.

When Iref is set to 10 μA, the voltage difference between the anode or cathode of the middle pixel and that of the edge pixel is about 1.0 V. When Iref is set to 20 μA, that voltage difference is about 2.0 V to achieve full brightness when displaying an image. These IR voltage drops create voltage differences that challenge displays requiring high image uniformity, especially when the supply voltage VDD is between 3 and 5 V.

When Iref is set to 10 μA, each equivalent one-dimensional electrode strip generates about 8.8 mW of heat. This increases to 35 mW at 20 μA to achieve full brightness when displaying an image. Under typical LED operating conditions for a 1280×720 high-definition pixel array, assuming the forward bias voltage of the LED is approximately 4.0 V, the photon power of fully illuminating LEDs in a scan row is about 51 mW when Iref is set to 10 μA, and about 102 mW when Iref is set to 20 μA. The IR drop effect results in significant power loss in the form of unnecessary heat within these equivalent one-dimensional electrode strips. This raises the components' operating temperature, leading to unstable operation and potentially reducing their lifespans.

In addition, a higher Iref value leads to an increase in the ratio of thermal power to photon power, mainly because the display operates at higher brightness levels with a higher Iref value. In practice, for a 1280×720 high-definition pixel array selecting 12 scan lines (SC) per scan, when Iref is set to 10 μA, the heat generated on the equivalent one-dimensional electrode row strips can reach about 105 mW. When Iref is set to 20 μA, it can reach 420 mW. This significant thermal power may pose challenges for effective heat dissipation of the display device, potentially causing an increase in surface temperature and adversely affecting the performance of the LEDs.

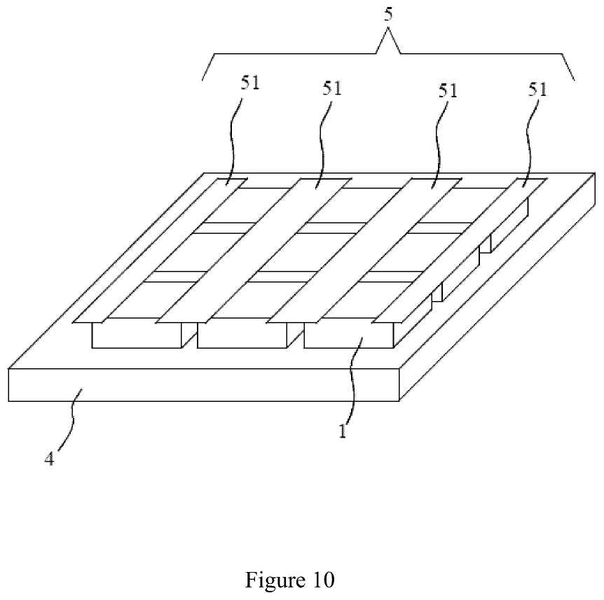

FIG. 10 illustrates an LED display device schematic according to one invention embodiment. Please look at FIGS. 4 and 10; the difference between FIG. 4 and FIG. 10 is in the shape of the common electrode layer 5. The two-dimensional grid shape of the common electrode layer 5 in FIG. 4 is replaced by multiple equivalent one-dimensional electrode strips 51, forming the common electrode layer 5 in FIG. 10. Therefore, the LED display device includes a control circuit layer 4, multiple electrodes 2, multiple light-emitting diodes (LEDs) 1, and a common electrode layer 5. The light-emitting diodes 1 can be, but are not limited to, semiconductor or organic light-emitting diodes. Each light-emitting diode 1 can be either a monochromatic or multi-color light-emitting diode.

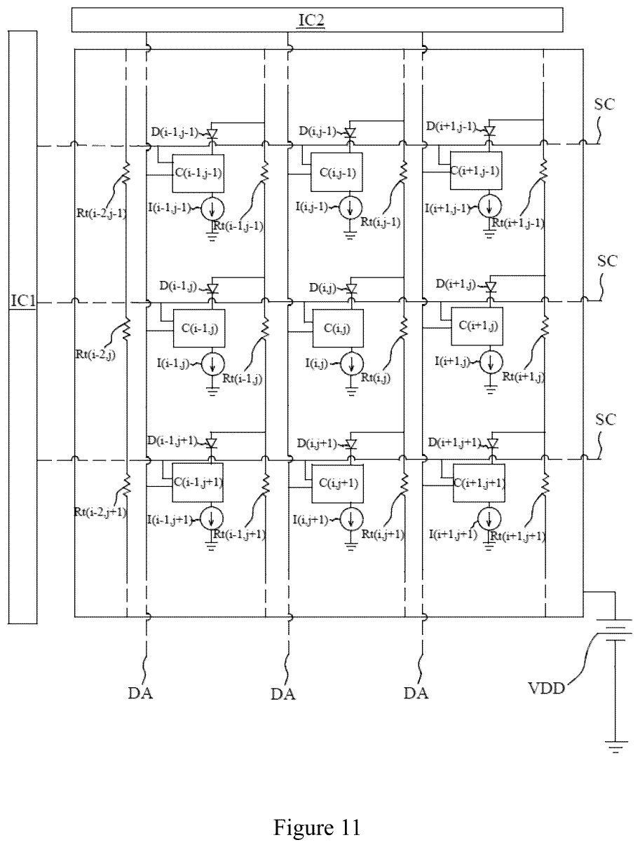

FIG. 11 corresponds to FIG. 10 but features a light-emitting diode array of size (m×n) that is not limited, along with an equivalent circuit diagram for the supply voltage VDD. In contrast to FIG. 5, FIG. 11 omits the horizontal parasitic resistors, while the remaining features are the same as in FIG. 5 and will not be elaborated upon here.

Please refer to FIGS. 2, 10, and 11. The control circuit layer 4 is coupled to multiple scanning lines (SC) and multiple data lines (DA), with SC and data lines DA intersecting perpendicularly. The electrodes 2 are located on the control circuit layer 4 and are coupled to the control circuit layer 4, with all electrodes 2 disconnected. The first conductive layer 10 of the light-emitting diode (LED) 1 is placed on the electrode 2 and is individually coupled to the electrode 2. The LEDs 1 are arranged in an array. The common electrode layer 5 consists of multiple equivalent one-dimensional electrode strips 51, including but not limited to conductive materials. One or both ends of the equivalent one-dimensional electrode strips 51 are coupled to the supply voltage VDD. These equivalent one-dimensional electrode strips 51 are positioned across multiple columns of the LED array 1 and are coupled to these columns, intersecting perpendicularly with the scanning lines SC. The control circuit layer 4 may contain multiple control circuits C(i,j) arranged in an array. The columns of control circuits C(i,j) columns are coupled to the data lines DA, and the rows of control circuits C(i,j) rows are coupled to the scanning lines SC. In addition to being connected to the first semiconductor layer 10 of the LED 1, the electrodes 2 are also coupled to the control circuits C(i,j). Moreover, the LED display device may include a first driver-integrated circuit IC1 and a second driver-integrated circuit IC2. The first driver, IC1, is coupled to the scanning lines SC, and the second, IC2, is coupled to the data lines DA. The area of the common electrode layer 5 in FIG. 10 is reduced by about half compared to FIG. 4, allowing for a larger optical aperture. Therefore, under the same bias conditions, pixels with equivalent one-dimensional electrode strips can achieve higher luminous efficiency than pixels with a two-dimensional mesh-like common electrode layer.

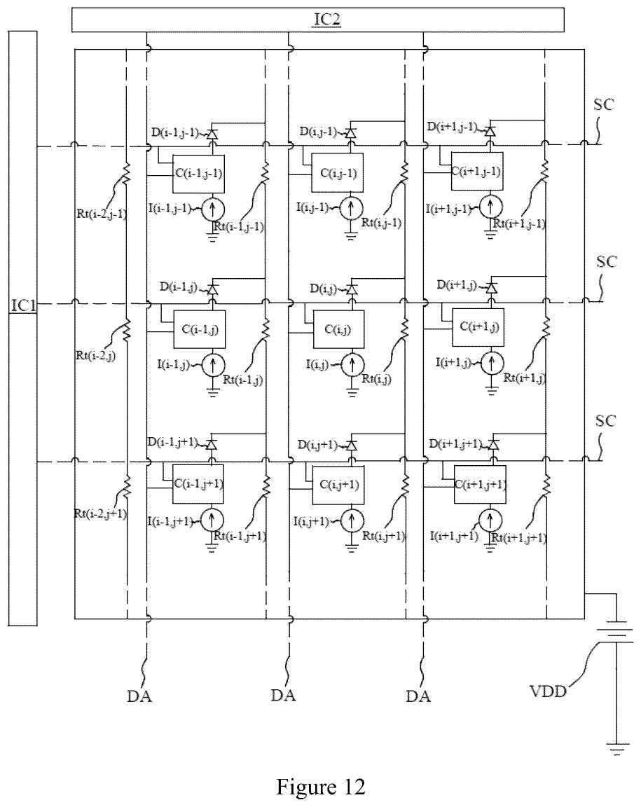

FIG. 12 presents another circuit diagram equivalent to FIG. 10. In contrast to FIG. 6, FIG. 12 omits the horizontal parasitic resistors. The remaining features are the same as in FIG. 6 and will not be elaborated upon here. The (m×n) display device can operate with multiple fixed numbers of lines selected for pixels during each scan.

The resistance of the equivalent one-dimensional electrode strips may cause an IR voltage drop effect in the (m×n) pixel array. The equivalent one-dimensional electrode strips can be manufactured according to design rules and manufacturing processes to ensure that the (m×n) pixel display device's transverse parasitic resistance closes to the horizontal parasitic resistance.

Assuming all activated pixels receive the same current Iref when displaying an image, the supply voltage VDD can supply the pixel current Iref. In an (m×n) pixel array with k scanning rows, the supply voltage VDD primarily provides current to the pixels during the scanning period. For example, when pixels in the row lines j=1 to j=k are chosen during the first scanning period. The same current Iref is supplied to each pixel. The voltage V_{TC,1} between the supply voltage VDD and the k-th row pixel can be expressed by formula (4), where Rt represents the value of the transverse parasitic resistance.

$$\begin{matrix}{V}_{TC , 1} \approx {\sum }_{j = 1}^{j = k} [ ( k - j + 1 ) \times Iref \times Rt ] \\ \approx \frac{k ( k + 1 )}{2} \times Iref \times Rt\end{matrix} \qquad ( 4 )$$

V_{TC,1} approaches the minimum voltage change V_{TC,min} of the IR voltage drop in the (m×n) display device. In simple terms, for an (m×n) pixel array with transverse parasitic resistance for each pixel during k line scanning, V_{TC,min} equals k(k+1)/2×Iref×Rt.

Another voltage drop is V_{TC,2}, which indicates the potential difference between the supply voltage VDD and the (k+1)-th row pixel during the second scanning period. This includes the voltage drop between the second-row pixel and the (k+1)-th row pixel throughout the process and the total voltage drop between the supply voltage VDD and the first-row pixel, as described in formula (5).

$$\begin{matrix}{V}_{TC , 2} \approx \{ {\sum }_{j = 2}^{j = k + 1} [ ( k - j + 2 ) \times Iref \times Rt ] \} + k \times Iref \times Rt ] \\ \approx \frac{k ( k + 1 )}{2} \times Iref \times Rt + k \times Iref \times Rt \\ \approx k ( k + 3 ) / 2 \times Iref \times Rt\end{matrix} \qquad ( 5 )$$

During the (n/2)-th scanning period, a current of k/2×Iref will flow from the upper supply voltage VDD to the pixels in the rows from j=(n/2−k/2+1) to j=n/2. In contrast, an equivalent current of k/2×Iref will be directed from the lower supply voltage VDD to the pixels in the rows from j (n/2+1) to j=(n/2+k/2). In this scanning period, the voltage V_{TC,n/2}, between the upper supply voltage VDD and the (n/2)-th row pixel will be the voltage drop across the transverse resistance of the light-emitting diodes in the rows from j=(n/2−k/2+1) to j=n/2, plus the total voltage drop from the upper supply voltage VDD to the light-emitting diodes in the j=(n/2−k/2) row. This relationship can be expressed as follows:

$$\begin{matrix}{V}_{TC , n / 2} \approx {\sum }_{j = \frac{n}{2} - \frac{k}{2} + 1}^{j = \frac{n}{2}} [ ( \frac{n}{2} - j + 1 ) \times Iref \times Rt ] + \frac{k}{2} \times Iref \times ( \frac{n}{2} - \frac{k}{2} ) \times Rt \\ \approx \frac{k ( 2 n - k + 2 )}{8} \times Iref \times Rt \\ \approx \frac{1}{4} n \times k \times Iref \times Rt , if n ≫ k / 2\end{matrix} \qquad ( 6 )$$

By utilizing the inherent transverse symmetry factor in the common electrode layer, it can be inferred that this represents the maximum voltage difference, denoted as V_{TC,max}, caused by the IR voltage drop in an (m×n) display device with equivalent one-dimensional electrode strips. Specifically, assuming k rows are scanned, for each pixel in an (m×n) pixel array with transverse parasitic resistance Rt, V_{TC,max} can be approximated as

$$\frac{1}{4} ( n \times k \times Iref \times Rt ) .$$

To analyze the electrical energy converted into heat in an (m×n) pixel array, the procedure of examining the IR voltage drop across k scan lines can be applied. It is evident that when the display device scans the row lines j=1 to j=k, the (m×n) pixel array exhibits approximately the lowest electrical power heat consumption due to the IR voltage drop effect. Conversely, when the display device scans the row lines j=(n/2−k/2+1) to j=(n/2+k/2), the (m×n) pixel array exhibits approximately the highest electrical power heat consumption due to the IR voltage drop effect. Under these conditions, to display an image at full brightness, each pixel receives a current of Iref from the supply voltage VDD. Due to the IR voltage drop effect on each equivalent one-dimensional electrode strip, the minimum electrical power converted into heat, denoted as W_{TC,1}, can be calculated using the formula (7).

$$\begin{matrix}{W}_{TC , 1} \approx {\sum }_{j = 1}^{j = k} \{ {[ ( k - j + 1 ) \times Iref ]}^{2} \times Rt \} \\ \approx \frac{k \times ( k + 1 ) \times ( 2 k + 1 )}{6} \times {Iref}^{2} \times Rt\end{matrix} \qquad ( 7 )$$

Due to the IR voltage drop effect on each equivalent one-dimensional electrode strip, half of the maximum electrical power converted into heat, denoted as W_{TC,n/2}, can be calculated using formula (8)

$$\begin{matrix}{W}_{TC , n / 2} \approx {\sum }_{j = \frac{n}{2} - \frac{k}{2} + 1}^{j = \frac{n}{2}} \{ {[ ( \frac{n}{2} - j + 1 ) \times Iref ]}^{2} \times Rt \} + {( \frac{k}{2} \times Iref )}^{2} \times ( \frac{n}{2} - \frac{k}{2} ) \times Rt \\ \approx \frac{1}{24} ( 3 {nk}^{2} - 2 {k}^{3} + 3 {k}^{2} + 2 k ) \times {Iref}^{2} \times Rt \\ \approx \frac{{nk}^{2}}{8} \times {Iref}^{2} \times Rt , if n ≫ k\end{matrix} \qquad ( 8 )$$

In an (m×n) pixel array, in the (n/2)-th scanning cycle, the total electric power balance dissipated in heat by the equivalent one-dimensional electrode strip is 2×m×W_{TC,n/2}. This represents the maximum power consumed by the equivalent one-dimensional electrode strips in an (m×n) pixel array using a k-line scanning scheme, driven by a constant current Iref to activate the pixel LEDs.

Based on the analysis results above, tables are compiled to compare the IR voltage drop and the subsequent power consumption generated by the equivalent one-dimensional electrode strips in FIGS. 7 and 10, using a 1280×720 LED display with parasitic resistance as an example. Monochrome images display the exact pixel values under 12 scanning line conditions, with Rh=Rt=0.5Ω and Iref=10 μA and 20 μA.

Table 1 enumerates the differences in minimum, maximum, and average voltage between the supply voltage VDD and the common electrode layer and the corresponding ratios of these differences to the LED bias, where the LED bias is approximately equal to or less than the supply voltage VDD. In the case of FIG. 7, each scanning interval presents a consistent voltage difference between the supply voltage VDD and the anode or cathode of the pixels in the row array's middle. When Iref=10 μA, this voltage difference is 1.0 V, approximately 26% of VDD=4V. When Iref=20 μA, the voltage difference is 2.0 V, approximately 51% of VDD=4V.

TABLE 1

| | | | | | the ratio |
|---|---|---|---|---|---|
| | | | | | of the |
| | | | | | average |
| | | | | | voltage |
| | | minimum | maximum | average | difference |
| | | voltage | voltage | voltage | in the |
| | | difference | difference | difference | distri- |
| | | in the | in the | in the | bution |
| | | distri- | distri- | distri- | of the |
| | | bution | bution | bution | common |
| | compliance | of the | of the | of the | electrode |
| | reference | common | common | common | layer to |
| | current, Iref, | electrode | electrode | electrode | the VDD |
| | uA | layer, V | layer, V | layer, V | voltage |
| equivalent | 10 | 1.0E+00 | 1.0E+00 | 1.0E+00 | 26% |
| 1D | 20 | 2.0E+00 | 2.0E+00 | 2.0E+00 | 51% |
| electrode | | | | | |
| strip in | | | | | |
| FIG. 7 | | | | | |
| equivalent | 10 | 3.9E−04 | 1.1E−02 | 5.6E−03 | 0.14% |
| 1D | 20 | 7.8E−04 | 2.2E−02 | 1.1E−02 | 0.28% |
| electrode | | | | | |
| strip in | | | | | |
| FIG. 10 | | | | | |

Rh = Rt = 0.5Ω, and VDD = 4 V

A similar analysis shows that, in the implementation example of FIG. 10, when the scanning area is close to the supply voltage VDD, the voltage difference between the supply voltage VDD and the anode or cathode of the activated LED is minimized. Conversely, when scanning the central area of the display device, the voltage difference is maximized. When Iref=10 μA, the minimum and maximum voltage differences are 0.39 mV and 11 mV, respectively. When Iref=20 μA, the minimum and maximum voltage differences are 0.78 mV and 22 mV, respectively. When Iref=10 μA, the average voltage difference relative to VDD=4V is approximately 0.14%; when Iref=20 μA, it is approximately 0.28%.

The ratio of the average voltage difference between LED biases to the fixed supply voltage VDD indicates the uniformity achieved in the pixel array image under this operation. A smaller ratio indicates a higher achievable image uniformity. The results in the table suggest that, compared to the pixel array in FIG. 7, the HD (1280×720) pixel array in FIG. 10 can achieve significantly superior image uniformity. Although not shown here, it is evident that for higher-resolution pixel arrays (e.g., FHD (1920×1080)), the display image uniformity superiority demonstrated by the implementation in FIG. 10 is expected to be even more pronounced compared to the HD (1280×720) pixel array provided in this example.

Considering the established relationships and the above conditions, as the reference current Iref increases to enhance the brightness of array pixels, the voltage difference between individual pixels and the supply voltage, the voltage variation between pixel anodes or cathodes, and the power consumed to heat become more apparent in the pixel array of FIG. 7. However, the anticipated impact of the implementation in FIG. 10 can be considered negligible, as this display device continues to operate under regular conditions with little deviation.

Table 2 illustrates the common electrode layer's minimum, maximum, and average power consumption in a 1280×720-pixel array. In the implementation of FIG. 7 with Rh=0.5Ω, the 12 rows of equivalent one-dimensional electrode strips consume 105 mW of electrical power per scan when Iref=10 μA and 420 mW when Iref=20 μA. While displaying an image, the energy consumed by the equivalent one-dimensional electrode strips of FIG. 7 remains constant for any active horizontal scan line. The bias determines the corresponding power for the LED, approximately equal to VDD=4V, disregarding the IR drop effect of the electrodes and the pixel current (represented as Iref).

When Iref=10 μA, the electrical power supplied to the LED pixel array per scan is calculated as 12×1280×4×10×10⁻⁶ W, i.e., 0.61 W for 12 scanned lines. Similarly, when Iref=20 μA, the power supplied to the LED pixel array is approximately 1.2 W. Compared to the required electrical power applied to the photon elements, the percentage of wasted heat power in the equivalent one-dimensional electrode strips of FIG. 7 is 17% when Iref=10 μA and 34% when Iref=20 μA. Furthermore, considering the electrodes' IR drop effect, the photon device's bias voltage will significantly decrease, and the percentage of thermal power loss in the electrodes relative to the LED power consumption will increase sharply.

TABLE 2

| | | | | | | the ratio of |
|---|---|---|---|---|---|---|
| | | | | | | the average |
| | | | | | | thermal powers |
| | | minimum | maximum | average | | of common |
| | | thermal | thermal | thermal | | electrode |
| | compliance | power of | power of | power of | | layers to |
| | reference | common | common | common | electrical | the electrical |
| | current Iref, | electrode | electrode | electrode | power of | powers of the |
| | uA | layer, W | layer, W | layer, W | LED, W | LEDs |
| equivalent | 10 | 1.1E−01 | 1.1E−01 | 1.1E−01 | 6.1E−01 | 17% |
| 1D | 20 | 4.2E−01 | 4.2E−01 | 4.2E−01 | 1.2E+00 | 34% |
| electrode | | | | | | |
| strip in | | | | | | |
| FIG. 7 | | | | | | |
| equivalent | 10 | 4.2E−05 | 1.7E−03 | 8.5E−04 | 6.1E−01 | 0.14% |
| 1D | 20 | 1.7E−04 | 6.6E−03 | 3.4E−03 | 1.2E+00 | 0.28% |
| electrode | | | | | | |
| strip in | | | | | | |
| FIG. 10 | | | | | | |

Rh = Rt = 0.5 Ω, and VDD = 4 V

In the embodiment of FIG. 10 with Rt=Rh=0.5Ω, the power consumption of the electrodes in all selected rows is minimized when the scanning area is near the supply voltage VDD and maximized when the scanning area is around the central region. When Iref=10 μA, the minimum power consumed by the 12 rows of equivalent one-dimensional electrode strips per scan is around 0.042 mW, and 0.17 mW when Iref=20 μA. In contrast, the maximum power consumed by the 12 rows of equivalent one-dimensional electrode strips per scan is around 1.7 mW when Iref=10 μA and 6.6 mW when Iref=20 μA.

Compared to the power provided to the LEDs for photon emission, the energy consumed by the equivalent one-dimensional electrode strips in FIG. 10 is negligible. For example, the ratio of thermal power of the electrode strips relative to the power of the LEDs is 0.14% and 0.28% when Iref=10 μA and Iref=20 μA, respectively. Therefore, there are virtually no IR voltage drop or thermal effect issues in the pixel array of FIG. 10. In other words, even if the current Iref needs to be increased to achieve higher brightness, there is still ample room for Iref adjustment without affecting the display device's excellent photon and image characteristics.

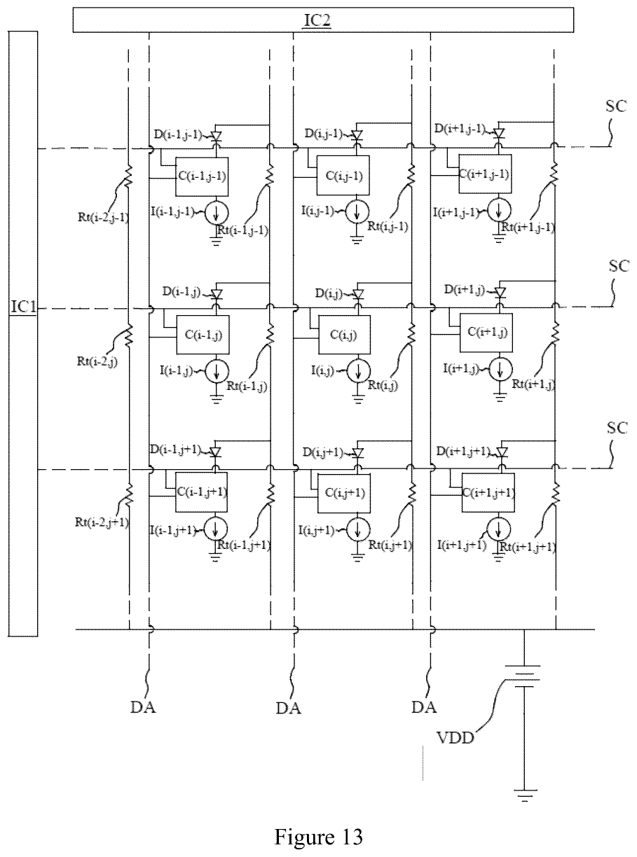

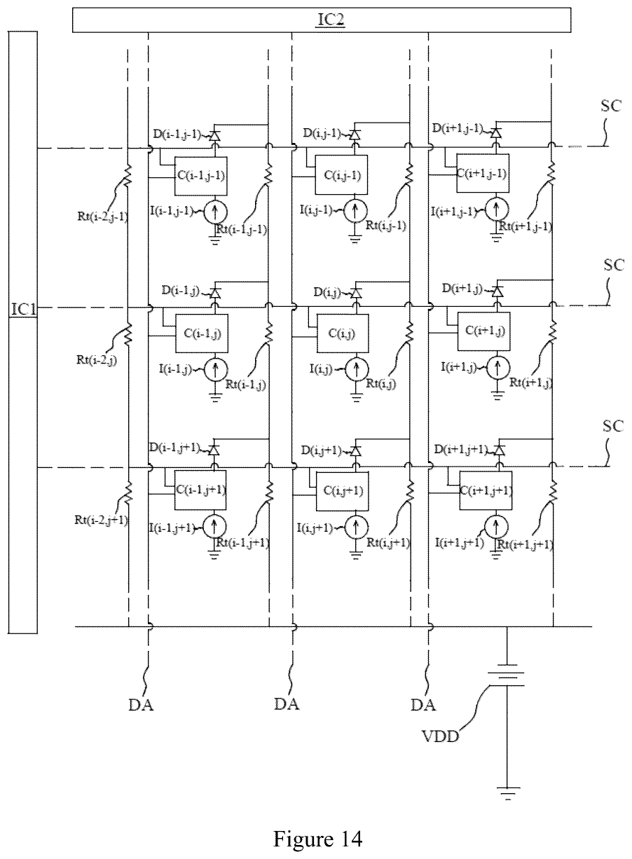

FIG. 13 is another circuit diagram that is equivalent to FIG. 10. Please take a look at FIGS. 10, 11, and 13. Compared to FIG. 11, in FIG. 13, one end of each equivalent one-dimensional electrode strip 51 is coupled to the supply voltage, while the other end is floating and not connected to different endpoints. The remaining features are the same as in FIG. 11, so they will not be repeated here. In this way, although the IR voltage drop and power consumption on the parasitic resistance of the equivalent one-dimensional electrode strip 51 in FIG. 13 are higher than in FIG. 11, they remain much lower than those in the equivalent one-dimensional electrode strips of FIG. 8. Thus, better pixel luminous efficiency, component operating stability, and lifespan can still be achieved. FIG. 14 is another circuit diagram equivalent to FIG. 10. Please take a look at FIGS. 10, 12, and 14. Compared to FIG. 12, in FIG. 14, one end of each equivalent one-dimensional electrode strip 51 is coupled to the supply voltage, while the other end is floating and not connected to different endpoints. The remaining features are the same as in FIG. 12, so they will not be repeated here. In this way, although the IR voltage drop and power consumption on the parasitic resistance of the equivalent one-dimensional electrode strip 51 in FIG. 14 are higher than in FIG. 12, they remain much lower than those in the equivalent one-dimensional electrode strips of FIG. 9. Thus, better pixel luminous efficiency, component operating stability, and lifespan can still be achieved.

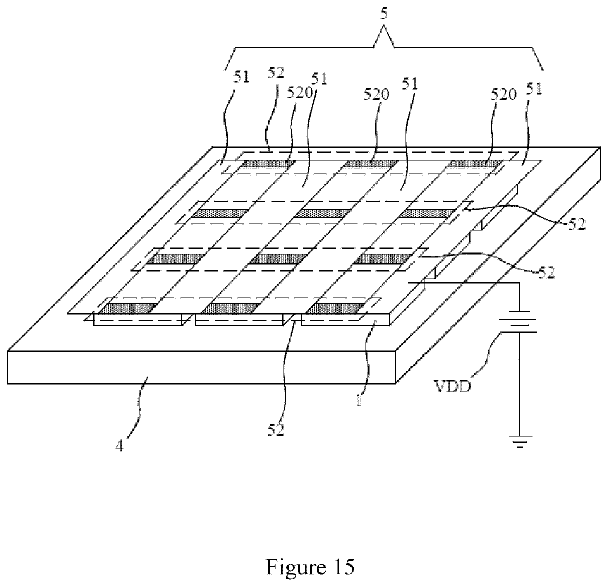

FIG. 15 is a schematic diagram of another embodiment of the light-emitting diode display device according to the present invention. Compared to the embodiment in FIG. 10, the common electrode layer 5 also includes multiple one-dimensional electrode segment groups 52 coupled to the equivalent one-dimensional electrode strips 51. All one-dimensional electrode segment groups 52 are arranged in parallel, forming a two-dimensional electrode mesh. Each one-dimensional electrode segment group 52 contains multiple one-dimensional electrode segments 520, which are coupled to the equivalent one-dimensional electrode strips 51 and arranged alternately with them. The one-dimensional electrode segment 520 is perpendicular to the equivalent one-dimensional electrode strip 51, wherein at least one end of each equivalent one-dimensional electrode strip 51 is coupled to a supply voltage. Since the width of each one-dimensional electrode segment 520 is smaller than that of each one-dimensional electrode strip 51, the embodiment in FIG. 15 can achieve the same effectiveness as the embodiment in FIG. 10.

The analysis of the common electrode layer's IR drop and power consumption scenario in FIG. 4 is quite complex. However, the trend can be approximated as the reciprocal of the sum of the reciprocal factors from FIGS. 7 and 10. Given that the voltage difference and power consumption in FIG. 7 are significantly higher than those in FIG. 10, it can be inferred that the situation in FIG. 4 is closer to that of FIG. 10.

The LED array with precisely defined pixels in FIG. 10 will exhibit optoelectronic characteristics and image quality similar to those in FIG. 4, and it will be significantly better than the LED array in FIG. 7. The adequate optical aperture size of the pixels in FIG. 10 is considerably larger than that of the pixel array in FIG. 4. Besides, the embodiment in FIG. 10 can provide greater layout flexibility in various layer structure designs of pixelated LEDs, especially for high-resolution display panels.

As described in this article, the common electrode layer in FIG. 10 has advantages over the one in FIG. 4, especially in high-density LED display devices, where the benefits are more pronounced. Fabricating equivalent one-dimensional electrode strips that are substantially perpendicular to the scan lines in LED and OLED pixel arrays and display panels represents the optimal implementation in this case.

According to the above embodiments, the LED display device forms equivalent one-dimensional electrode strips that substantially intersect the scan lines perpendicularly, reducing the impact of the current resistance (IR) drop in the common electrode layer. This embodiment significantly improves the pixel aperture ratio, achieving superior pixel light emission efficiency and enhancing pixel emission uniformity with lower power consumption.

A comparison of the above analysis shows that when the width of the electrode strips in the direction parallel to the scan lines in the two-dimensional common electrode layer is smaller than the width of the electrode strips corresponding to the substantially perpendicular to the scan lines, resulting in Rh>Rt, the conductive effect and performance of such a two-dimensional common electrode layer are equivalent to the results of the substantially perpendicular scan line electrode strips in this patent application. Therefore, it is included within the scope of this patent application.

The embodiments serve only as examples of the invention and do not limit its scope. Therefore, any equivalent modification or variation according to the shapes, structures, features, or spirit disclosed by the invention is to be also included within the scope of the invention.

What is claimed is:

1. A light-emitting diode display device comprising:
a control circuit layer coupled to multiple scan lines and multiple data lines, wherein the multiple scan lines and the multiple data lines substantially intersect at right angles;
multiple electrodes arranged on the control circuit layer and coupled to the control circuit layer, wherein the multiple electrodes are disconnected from each other;
multiple light-emitting diodes respectively arranged on and coupled to the multiple electrodes, wherein the multiple light-emitting diodes are arranged in an array; and
a common electrode layer comprising a plurality of equivalent one-dimensional electrode strips, wherein at least one end of each of the plurality of equivalent one-dimensional electrode strips is coupled to a supply voltage, the plurality of equivalent one-dimensional electrode strips are respectively disposed on multiple columns of the array of the plurality of light-emitting diodes and are coupled to the multiple columns of the array of the plurality of light-emitting diodes, substantially intersecting the multiple scan lines perpendicularly.

2. The light-emitting diode display device according to claim 1, wherein the common electrode layer further includes a plurality of one-dimensional electrode segment groups coupled to the plurality of equivalent one-dimensional electrode strips; the plurality of one-dimensional electrode segment groups are arranged in parallel, with each of the plurality of one-dimensional electrode segment groups comprising multiple one-dimensional electrode segments; the multiple one-dimensional electrode segments are coupled to the plurality of equivalent one-dimensional electrode strips, arranged alternately with them, and substantially perpendicular to them; width of each of the plurality of equivalent one-dimensional electrode strips is greater than that of each of the multiple one-dimensional electrode segments.

3. The light-emitting diode display device according to claim 1, further comprising:
a first driving integrated circuit coupled to the multiple scan lines; and
a second driving integrated circuit coupled to the multiple data lines.

4. The light-emitting diode display device according to claim 1, wherein the control circuit layer comprises a plurality of control circuits arranged in an array, with multiple columns of the control circuits respectively coupled to the multiple data lines and multiple rows of the control circuits respectively coupled to the multiple scan lines, the plurality of electrodes are respectively disposed on the plurality of control circuits and coupled to the plurality of control circuits.

5. The light-emitting diode display device according to claim 1, wherein the plurality of equivalent one-dimensional electrode strips comprise a conductive material.

6. The light-emitting diode display device according to claim 1, wherein the multiple light-emitting diodes are semiconductor or organic light-emitting diodes.

7. The light-emitting diode display device according to claim 1, wherein each of the multiple light-emitting diodes comprises a monochromatic or multicolored light-emitting diode.

8. The light-emitting diode display device according to claim 1, wherein the multiple electrodes serve as cathodes and the common electrode layer is an anode.

9. The light-emitting diode display device according to claim 1, wherein the multiple electrodes serve as anodes and the common electrode layer is a cathode.

10. The light-emitting diode display device according to claim 1, wherein both ends of each of the plurality of equivalent one-dimensional electrode strips are coupled to the supply voltage.

11. The light-emitting diode display device according to claim 2, wherein both ends of each of the plurality of equivalent one-dimensional electrode strips are coupled to the supply voltage.
